(19) United States
(12) Patent Application Publication
(10) Pub. No.: US 2011/0237003 A1
(43) Pub. Date: Sep. 29, 2011

(54) METHOD OF MANUFACTURING SEMICONDUCTOR DEVICE BY USING COMPRESSION MOLDING

(75) Inventor: Toyoto MASUDA, Kanagawa (JP)

(73) Assignee: RENESAS ELECTRONICS CORPORATION, Kawasaki-shi (JP)

(21) Appl. No.: 13/070,111

(22) Filed: Mar. 23, 2011

(30) Foreign Application Priority Data
Mar. 24, 2010 (JP) 2010-067208

(51) Int. Cl. H01L 21/56

(52) U.S. Cl. 438/15; 257/E21.504

(57) ABSTRACT

A method of manufacturing a semiconductor device comprises: determining whether or not the viscosity of a sealing resin at a first temperature lower than the melting temperature of the sealing resin is less than or equal to a first reference value which prevents poor sealing from occurring at the first temperature, for each lot in which the corresponding sealing resin is manufactured; selecting the sealing resin of the lot when the viscosity of the sealing resin at the first temperature is less than or equal to the first reference value; introducing the sealing resin selected in selecting the sealing resin into a mold of a compression molding apparatus; and sealing a semiconductor chip mounted over a substrate with the sealing resin by compression molding using the mold heated at a second temperature higher than the first temperature after introducing the sealing resin.

This application is based on Japanese patent application No. 2010-067208, the content of which is incorporated herein by reference.

### BACKGROUND

1. Technical Field

The present invention relates to a method of manufacturing a semiconductor device, particularly to a method of manufacturing a semiconductor device in which a semiconductor chip is sealed in a compression molding process.

2. Related Art

Techniques are known in which after a semiconductor chip is mounted on a substrate, the semiconductor chip is sealed with a sealing resin to form a semiconductor package. Techniques for forming the semiconductor package with the sealing resin include, for example, a compression molding process, a transfer molding process, a potting process, or a printing process and the like. Among them, the compression molding process is a process having an excellent low wire flow because of a small flow of the sealing resin at the time of sealing, and thus the development thereof has recently progressed.

Japanese Unexamined Patent Publication No. 2006-070197 and Japanese Unexamined Patent Publication No. 2008-121003 disclose techniques for forming the semiconductor package with the sealing resin using the compression molding process.

Japanese Unexamined Patent Publication No. 2006-070197 discloses a compression molding resin composition, which is a resin composition containing (A) an epoxy resin, (B) a phenol resin curing agent and (C) an inorganic filler, respectively, as essential ingredients, of which the viscosity at the melting temperature is equal to or lower than 15 Pa·s, and the gel time is 45 to 80 seconds. Here, the melting temperature is stated to be 175° C. Thereby, it is described that it is possible to suppress defects due to deformation of a bonding wire occurring at the time of resin seal molding of a semiconductor element, and to prevent voids from being generated by improving the resin filling property.

Japanese Unexamined Patent Publication No. 2008-121003 discloses a sealing epoxy resin molding material which contains (A) an epoxy resin, (B) a curing agent and (C) an inorganic filling material, the above-mentioned (A) epoxy resin has two or more epoxy groups in one molecule, the melt viscosity at the temperature of 150° C. is 0.1 Pa·s or less, and an ingredient having a powder grain size of more than or equal to 106 μm in the sealing epoxy resin molding material is present at more than or equal to 97% by weight. Here, it is also stated that the mold temperature at the time of compression molding is set to 175° C.

Hitherto, for example, as disclosed in Japanese Unexamined Patent Publication No. 2008-121003, the mold temperature at the time of compression molding has been set to approximately 175° C. In addition, the characteristics of the viscosity and the like of the sealing resin used in a compression molding process have been evaluated based on the characteristics at the melting temperature of the sealing resin or the mold temperature at the time of compression molding, for example, as disclosed in Japanese Unexamined Patent Publication No. 2006-070197.

### SUMMARY

However, the inventor has found that even when the characteristics at the melting temperature of the sealing resin or the mold temperature at the time of compression molding satisfy a predetermined reference, there may be a case where poor sealing such as wire deformation (wire crushing) occurs. When such wire crushing occurs, defects leading to a poor short circuit are generated. The inventor has examined this cause and has found that in a compression molding process, even when the mold is heated to a predetermined temperature, variation in the temperature of the sealing resin with location occurs.

In addition, the inventor has found, as a result of further examination, that even when the characteristics at the melting temperature of the sealing resin or the mold temperature at the time of compression molding satisfy a predetermined reference, variation exists in the characteristics at the lower temperature due to variation and the like in each of the raw materials. When such variation exists, the viscosity of the sealing resin becomes improperly high at a spot having a low temperature. For this reason, it is considered that the wire is crushed at the time of compression molding, which leads to the generation of the wire crushing. Hitherto, the existence of such variation has not been recognized, and the selection of the sealing resin has been determined only by the characteristics at the melting temperature of the sealing resin having a higher temperature or the mold temperature at the time of compression molding.

According to an aspect of the present invention, there is provided a method of manufacturing a semiconductor device, which comprises: determining whether or not the viscosity of a sealing resin at a first temperature lower than the melting temperature of the sealing resin is less than or equal to a first reference value which prevents poor sealing from occurring at the first temperature, for each lot in which the corresponding sealing resin is manufactured; selecting the sealing resin of the lot when the viscosity of the sealing resin at the first temperature is less than or equal to the first reference value; introducing the sealing resin selected in selecting the sealing resin into a mold of a compression molding apparatus; and sealing a semiconductor chip mounted over a substrate with the sealing resin by compression molding using the mold heated at a second temperature higher than the first temperature after introducing the sealing resin.

According to such a configuration, it is possible to use a resin of which the viscosity at the first temperature lower than the second temperature applied to the mold at the time of compression molding is less than or equal to the first reference value which prevents poor sealing from occurring at the first temperature, as the sealing resin used in the compression molding process. Thereby, even when a spot having a low temperature in the sealing resin exists at a location at the time of heating the mold to a predetermined temperature, it is possible to use the sealing resin of which the viscosity is low to an extent that poor sealing does not occur. Thereby, it is possible to provide a manufacturing method having excellent sealing stability which prevents poor sealing such as wire crushing from occurring.

Meanwhile, arbitrary combinations of the above-mentioned components, and ones obtained by conversion of the expression of the invention among methods, devices and the like are also effective as the aspect of the invention.

According to the aspect of the invention, it is possible to prevent poor sealing in the compression molding process from occurring.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are schematic diagrams illustrating procedures for sealing a semiconductor chip with a sealing resin using a compression molding apparatus in an embodiment of the invention;

FIG. 2 is a diagram illustrating the change of temperature with time of the sealing resin in a plurality of locations at the time of heating a lower mold of the compression molding apparatus to a temperature of 175° C.;

FIG. 3 is a diagram illustrating the relationship between the temperature and the viscosity of a sealing resin a and a sealing resin b of different manufactured lots;

FIG. 4 is a flowchart illustrating procedures of a compression molding process in manufacturing a semiconductor device in the embodiment of the invention;

FIG. 5 is a diagram illustrating the relationship between the viscosity and the incidence of wire deformation for each of the sealing resins at a temperature of 120° C.;

FIG. 6 is a diagram illustrating an example of the configuration of the compression molding apparatus in the embodiment of the invention; and

FIG. 7 is a diagram illustrating another example of the configuration of the compression molding apparatus in the embodiment of the invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

### (First Embodiment)

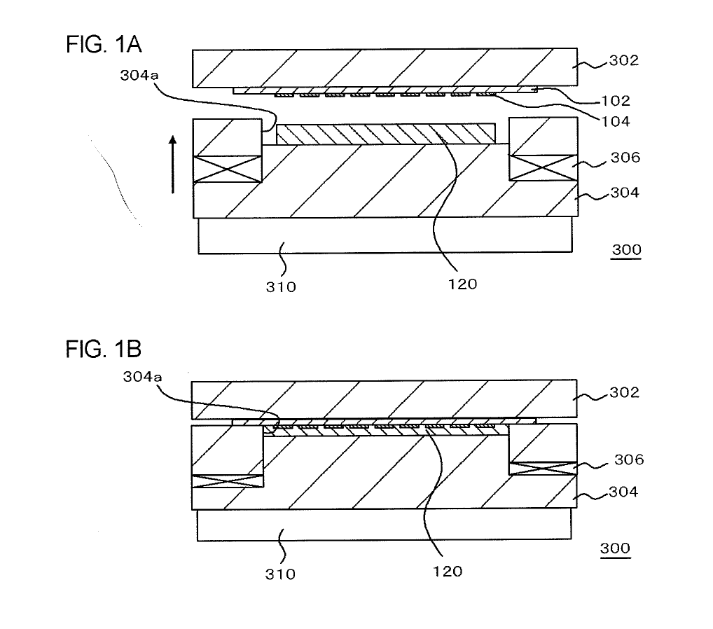

FIGS. 1A and 1B are schematic diagrams illustrating procedures for sealing a semiconductor chip with a sealing resin using a compression molding apparatus and connecting a semiconductor device thereto in the embodiment.

Compression molding apparatus 300 includes a lower mold 304 (mold) having a cavity 304a on which a sealing resin 120 is disposed, and an upper mold 302 (mold). A spring 306 is attached between the external wall of the cavity 304a and the main body of the lower mold 304. In the compression molding apparatus 300 having such a configuration, a substrate 102 is attached to the upper mold 302 so that a semiconductor chip 104 mounted on the substrate 102 faces the lower mold 304. Subsequently, the sealing resin 120 is introduced into the cavity 304a of the lower mold 304 (FIG. 1A).

Here, the substrate 102 can be formed as a multilayer interconnect substrate in which there is a plurality of interconnect layers which are connected to each other. In addition, the semiconductor chip 104 can be configured to be electrically connected to the substrate 102 through a bonding wire (not shown). In the embodiment, when the semiconductor chip 104 is sealed with the sealing resin 120 by compression molding, the bonding wire is also sealed with the sealing resin 120.

In the embodiment, the sealing resin can made of a resin usually used as a compression molding resin composition. The sealing resin can include, as raw materials, a resin used as a base resin, a curing agent, and an inorganic filling agent (filler). The sealing resin can be made of, for example, a thermosetting epoxy resin. Here, the resin used as a base resin can be made of at least an epoxy resin having two or more epoxy groups within molecules. The curing agent can be made of an agent having a hydroxyl group with reactivity with an epoxy group. The inorganic filler can be made of, for example, silica or an alumina filler and the like. In addition, the sealing resin can further include, as raw materials, a flexible agent, a hardening accelerator, a latent catalyst, a mold release agent, silicon oil, a low stress agent, a coloring agent and the like.

Meanwhile, the form of the sealing resin 120 can take an arbitrary form, and can be is made of, for example, a preform body or a granular resin before formation as the preform body or a resin composition before hardening which is a mass with the granular resin formed as a tablet.

In such a state, the lower mold 304 is heated to a predetermined temperature. At this time, heating of the lower mold 304 is performed by a heating portion 310 such as a heater provided below the lower mold 304. Next, the semiconductor chip 104 mounted on the substrate 102 is sealed with the sealing resin 120 by compression molding using the lower mold 304 heated at the predetermined temperature. Specifically, the lower mold 304 is pressed in the direction of the external wall of the cavity 304a. Thereby, the external wall of the cavity 304a is moved in the direction of the main body of the lower mold 304, the depth of the cavity 304a becomes shallow, and the sealing resin 120 set within the cavity 304a is melted and cured to thereby be compression-molded (FIG. 1B).

Incidentally, the inventor has found that even when the characteristics at the temperature of 175° C. which is a melting temperature of the sealing resin or a mold temperature at the time of compression molding satisfy a predetermined reference, there may be a case where poor sealing such as wire deformation (wire crushing) occurs. When such wire crushing occurs, defects leading to a poor short circuit are generated.

The inventor has examined this cause and has found that in a compression molding process, when the lower mold 304 is heated to a predetermined temperature, and the semiconductor chip 104 mounted on the substrate 102 is sealed with the sealing resin 120 by compression molding, variation in the temperature of the sealing resin 120 with location occurs.

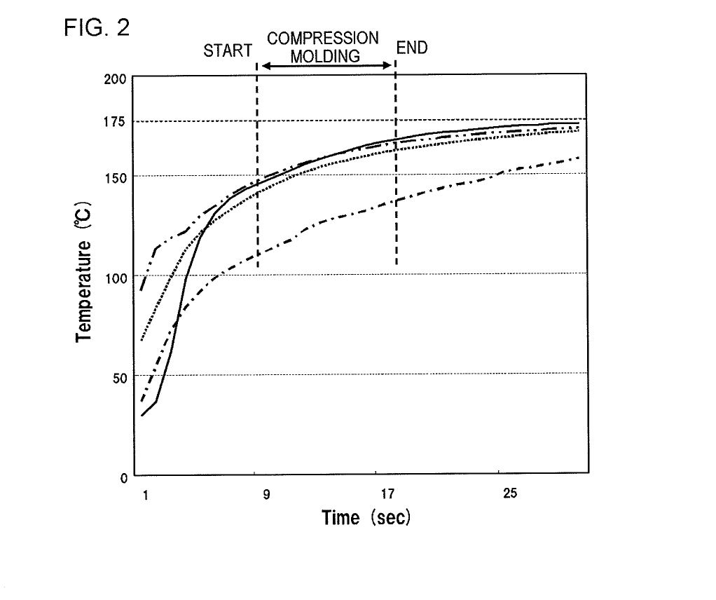

FIG. 2 is a diagram illustrating the change of temperature with time of the sealing resin 120 in a plurality of locations at the time of heating the lower mold 304 to a temperature of 175° C. Each of the lines corresponds to the temperatures of each of the locations. The horizontal axis in the drawing denotes time (sec) from the start of heating, and the vertical axis denotes temperature (° C.) of the sealing resin 120 in each of the locations. Herein, heating is started and compression molding is started after approximately 9 seconds, and then compression molding is ended after 17 seconds.

As shown in FIG. 2, it is found that even when the lower mold 304 is heated to a temperature of 175° C., the sealing resin 120 does not reach a temperature of 175° C., and the lowest temperature of the sealing resin 120 during compression molding is merely 110° C. or so depending on location. Particularly, the temperature in the surface of the sealing resin 120 is low. In addition, when the heating time is lengthened, the temperature of the sealing resin 120 is gradually higher. However, when the heating time is excessively lengthened, there may be a possibility that the sealing resin 120 is hardened, and thus the heating time cannot be lengthened. Further, when the heating time is excessively lengthened, cost performance decreases.

As shown in FIGS. 1A and 1B, in the compression molding process, the sealing resin 120 is placed in the lower mold 304, and heating is performed in the state where the sealing resin 120 is released in the atmosphere. In addition, only the lower mold 304 is heated. In addition, it is considered that the sealing resin 120 may be foamed, and such variation in the temperature with location occurs.

In addition, the inventor has found, as a result of further examination, that even when the characteristics at the temperature of 175° C. which is a melting temperature of the sealing resin or a mold temperature at the time of compression molding satisfy a predetermined reference, variation exists in the characteristics at a lower temperature due to variation and the like in each of the raw materials.

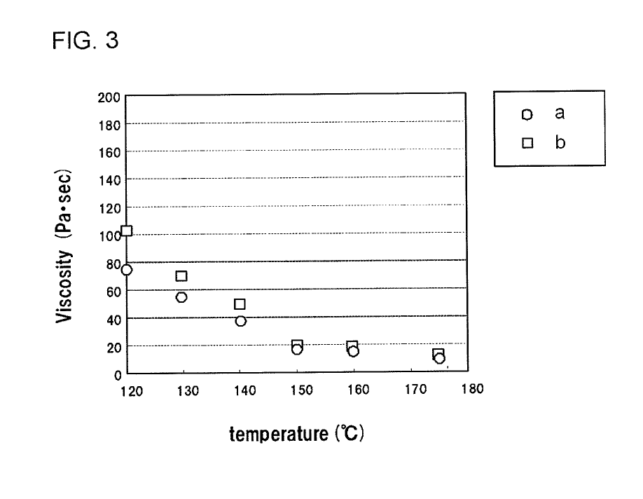

FIG. 3 is a diagram illustrating the relationship between the temperature and the viscosity of a sealing resin a and a sealing resin b of different manufactured lots.

Here, the sealing resin a and the sealing resin b are manufactured with the same material and conditions except that the manufactured lots are different from each other. In addition, the sealing resin a and the sealing resin b are all resins determined to be non-defective products in which the melt viscosity and the gel time at the temperature of 175° C. satisfy a predetermined reference value. An Au wire (25 μφ) is used as a bonding wire.

Using such a sealing resin a and a sealing resin b, as described with reference to FIGS. 1A and 1B, when the semiconductor chip 104 having a bonding wire is sealed by the compression molding process, deformation and the like of the bonding wire do not occur in the case where the sealing resin a is used, and satisfactory sealing is performed. On the other hand, in the case where the sealing resin b is used, deformation and the like of the bonding wire occur, and thus poor sealing occurs.

As shown in FIG. 3, the sealing resin a and the sealing resin b all have almost the same melt viscosity at the temperature of 175° C. However, the viscosity at the temperature of 120° C. is approximately 74 Pa·sec in the sealing resin a, and on the other hand, the viscosity is approximately 101 Pa·sec in the sealing resin b.

In the manner, it is found that even when the difference does not appear in the characteristics at the high temperature of 175° C. with respect to the manufactured lot, variation exists in the characteristics at the low temperature. The sealing resin has viscosity characteristics based on each structure in the range having a certain variation of the manufactured lot, in response to variation in molecular weight of each of the raw materials. However, since the influence of the thermal motion of the molecules is strong at the high temperature of 175° C., it is considered that the influence of variation in molecular weight of each of the raw materials is not sufficiently reflected, and variation in the viscosity characteristics does not appear. For this reason, hitherto, it can be considered that variation of the viscosity with the lot has not been recognized.

Hitherto, it has not been considered that variation in the temperature of the sealing resin with location occurs at the time of compression molding, and the viscosity at the low temperature of the sealing resin used in compression molding has not been considered. For this reason, hitherto, the sealing resin used in compression molding has been evaluated on the basis of the characteristics at the high temperature (for example, 175° C.) which is a heating temperature of the mold. However, when variation in the temperature with location exists at the time of compression molding, and variation also exists in the characteristics of the sealing resin at the low temperature, and it is considered that in a spot having a low temperature, the viscosity of the sealing resin becomes improperly high. Thereby, it is considered that the wire is crushed at the time of compression molding, which leads to the generation of the wire crushing.

The inventor considered that variation in the viscosity of the sealing resin at the lower temperature exists as a result of the lot in which each of the sealing resins is manufactured, and when the sealing resin of which the viscosity in the low temperature becomes high is used, poor sealing occurs together with variation in the temperature of the sealing resin with location at the time of compression molding, and then deduced the invention.

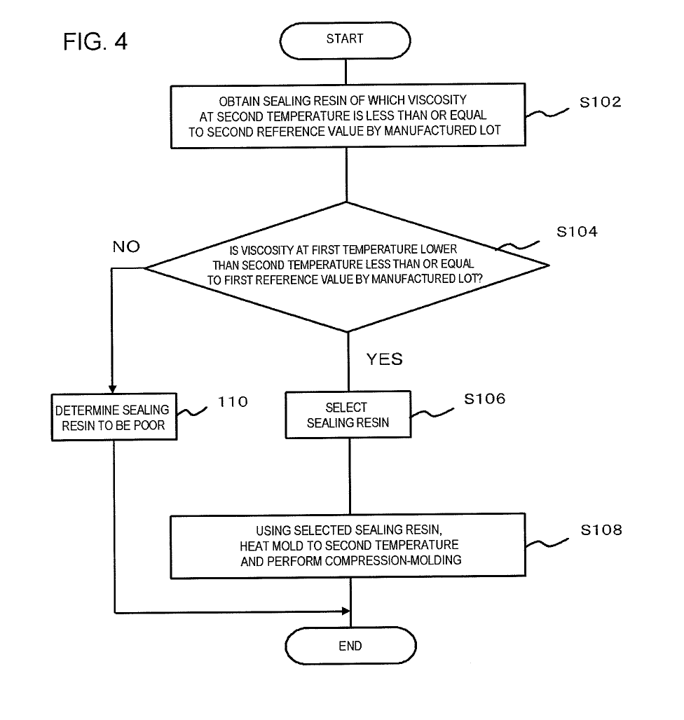

FIG. 4 is a flowchart illustrating procedures of a compression molding process in manufacturing the semiconductor device in the embodiment.

In the embodiment, first, the sealing resin of which the viscosity at a second temperature is less than or equal to a second reference value which prevents poor sealing from occurring at the second temperature is obtained by the lot in which the corresponding sealing resin is manufactured (hereinafter, referred to as the manufactured lot) (step S102). That is, in the embodiment, it is possible to perform processing for selecting the following sealing resin, for the sealing resin of which the viscosity at the second temperature is less than or equal to the second reference value. Here, the second temperature can be set to a temperature at which the lower mold 304 of the compression molding apparatus 300 is heated. In addition, the second temperature can be set to be equal to or higher than the melting temperature of the sealing resin. For example, the second temperature can be set to 175° C. Meanwhile, in the embodiment, a second sealing resin can be made of a resin that satisfies the above-mentioned second reference value in the range of the second temperature ±10° C. Here, the second reference value can be set to be less than or equal to a first reference value described later.

Subsequently, it is determined whether or not the viscosity at the first temperature lower than the second temperature is less than or equal to the first reference value which prevents poor sealing from occurring at the first temperature, by the manufactured lot, with respect to the sealing resin obtained in step S102 (step S104). The first temperature can be set to a temperature lower than the melting temperature of the sealing resin. In addition, the first temperature can be set on the basis of variation in the temperature of the sealing resin between the start of compression molding and the end thereof when the lower mold 304 is heated at the second temperature and the semiconductor chip 104 mounted on the substrate 102 is sealed with the sealing resin by compression molding. Here, the first temperature can be set to an average value, from the start of compression molding to the end thereof, of the temperature of the location having the lowest temperature of the sealing resin 120 during compression molding. For example, the first temperature can be set to 120° C. based on the example shown in FIG. 3.

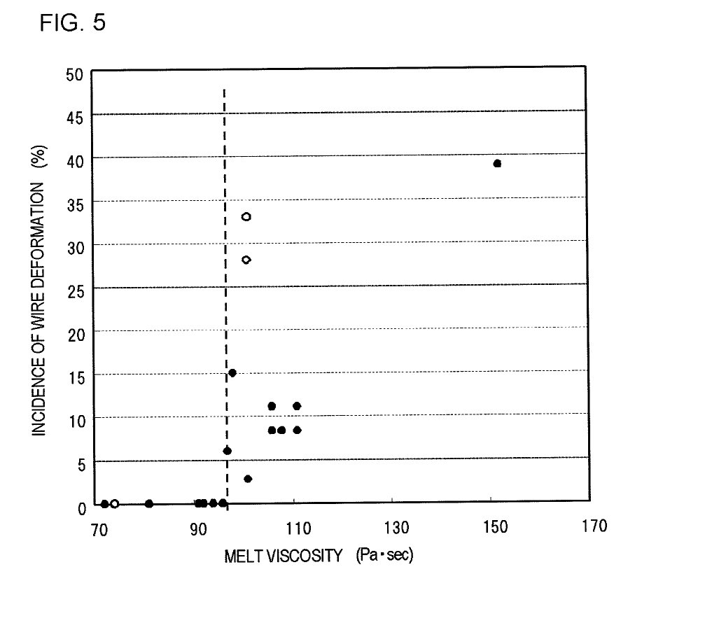

FIG. 5 is a diagram illustrating the relationship between the viscosity and the incidence of wire deformation for each sealing resin at the temperature of 120° C. Here, an Au wire (25 μmΦ) is used as a bonding wire that connects the semiconductor chip 104 and the substrate 102. The height of the bonding wire (distance from the surface of the substrate 102 to the position at which the bonding wire is highest) is set to a range from 0.1 mm to 0.7 mm, but there is little height dependency. Herein, plural types of resins including the sealing resin a and the sealing resin b described with reference to FIG. 3 are used as the sealing resin.

As shown in FIG. 5, when the viscosity at the temperature of 120° C. is less than or equal to 95 Pa·sec in any of the sealing resins regardless of the height of the bonding wire, wire deformation does not occur. On the other hand, when the viscosity at the temperature of 120° C. is higher than 95 Pa·sec, wire deformation occurs. From the above, the first reference value can be set to, for example, 95 Pa·sec.

Meanwhile, processing of step S104 can include a step of measuring the viscosity for each manufactured lot with respect to the obtained sealing resin. In addition, it is possible to determine whether or not the viscosity at the first temperature is less than or equal to the first reference value for each lot in which the corresponding sealing resin is manufactured, on the basis of the measurement result. In this case, the measurement of the viscosity can be performed using an elevation-type flow tester viscometer.

In addition, as another example, it is also possible to obtain, for example, as a list, a result of measuring whether or not the viscosity at the first temperature is less than or equal to the first reference value for each manufactured lot, together with the sealing resin, from a manufacturer of the sealing resin, and to determine the processing of step S104 on the basis of the result.

Next, if the viscosity of the sealing resin measured in step S104 is less than or equal to the first reference value (YES in step S104), the corresponding sealing resin is selected as a resin used in compression molding (step S106). On the other hand, if the viscosity of the sealing resin measured in step S104 is greater than the first reference value (NO in step S104), the corresponding sealing resin is determined to be poor (step S110), and the processing is ended.

Subsequently, the lower mold 304 of the compression molding apparatus 300 is heated to the second temperature and is compression-molded using the sealing resin selected in step S108 (step S108).

As described above, in step S102 and step S104, an example of selecting the sealing resin is shown on the basis of only the viscosity of the sealing resin. However, at the time of the selection of the sealing resin, it is also possible to consider the gel time which is an index of the hardening rate. For example, in step S104, first, it is also determined whether the gel time of the sealing resin at the first temperature satisfies a predetermined reference value or not. Next, when the viscosity of the sealing resin is less than or equal to the first reference value, and the gel time of the sealing resin satisfies a predetermined reference value, it is also possible to select the corresponding sealing resin in step S106. Here, the predetermined reference value of the gel time of the sealing resin can be set to be, for example, more than or equal to 30 seconds and less than or equal to 70 seconds.

Next, an effect of the procedures for manufacturing the semiconductor device in the embodiment will be described.

In the embodiment, it is possible to use a resin of which the viscosity at the first temperature lower than the second temperature applied to the mold at the time of compression molding is less than or equal to the first reference value which prevents poor sealing from occurring at the first temperature, as the sealing resin used in the compression molding process. Thereby, even when a spot having a low temperature of the sealing resin exists at a location at the time of heating the mold to a predetermined temperature, it is possible to use the sealing resin of which the viscosity is low to an extent that poor sealing does not occur. Thereby, it is possible to provide a manufacturing method having excellent sealing stability which prevents poor sealing such as wire crushing from occurring.

Thereby, a decrease in the yield ratio does not occur.

### (Second Embodiment)

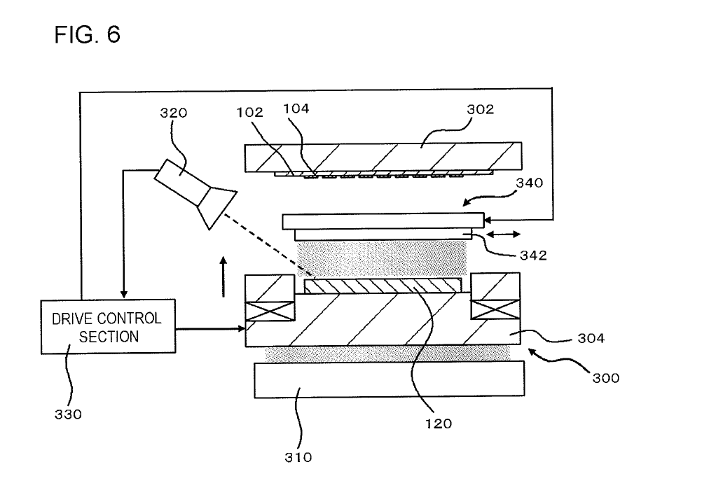

FIG. 6 is a diagram illustrating an example of the configuration of the compression molding apparatus 300 in the embodiment.

In the embodiment, the compression molding apparatus 300 further includes an upper-surface heating portion 340, a thermometer 320, and a drive control section 330 in addition to the configuration shown in FIGS. 1A and 1B.

As mentioned above, the inventor has found that when the lower mold 304 is heated to a predetermined temperature in the compression molding process, variation in the temperature of the sealing resin 120 by location occurs at the time of sealing the semiconductor chip 104 mounted on the substrate 102 with the sealing resin 120 by compression molding. Here, particularly in the surface (upper surface) of the sealing resin 120, the temperature of the sealing resin 120 decreases. For this reason, in the embodiment, control is performed in which the sealing resin 120 is preheated even from the upper surface thereof, the temperature of the sealing resin 120 is monitored and reaches a constant temperature, and then compression molding is carried out.

Consequently, in the embodiment, when compression molding is performed by the compression molding apparatus 300, control is performed in which the sealing resin 120 is heated even from the upper surface thereof, the temperature of the sealing resin 120 is monitored, the temperature of the sealing resin 120 becomes sufficiently high, and then compression molding is started.

The upper-surface heating portion 340 includes, for example, a heater 342 such as an infrared heater. The heater 342 is configured such that when the sealing resin 120 is introduced into the cavity of the lower mold 304, the sealing resin 120 is heated from the upper surface thereof. The thermometer 320 can be, for example, a noncontact thermometer such as a radiation thermometer. The thermometer 320 may be configured such that when the sealing resin 120 is introduced into the cavity of the lower mold 304, the temperature of a plurality of arbitrary positions on the upper surface of the sealing resin 120 is able to be measured. In addition, for example, the thermometer may be configured to measure the temperature of the spot in which the temperature easily becomes lowest.

The drive control section 330 controls the drive of the lower mold 304 and the upper-surface heating portion 340. In addition, in the drive control section 330, control is performed so that the temperature of the surface of the sealing resin 120 reaches a constant temperature or higher and then compression molding is carried out, on the basis of the temperature measured by the thermometer 320. Here, the predetermined temperature can be set to, for example, 150° C.

Meanwhile, the control function of the drive control section 330 can also be realized by installing a predetermined program in, for example, a personal computer and the like.

Next, the procedures of the compression molding process of the compression molding apparatus 300 in the embodiment will be described. First, the sealing resin 120 is heated by the heating portion 310 and the upper-surface heating portion 340. The thermometer 320 measures the temperature of the sealing resin 120. The drive control section 330 acquires the temperature measured by the thermometer 320, and determines whether or the temperature reaches a predetermined reference temperature or higher. When the temperature reaches a predetermined reference temperature or higher, the drive control section 330 moves the upper-surface heating portion 340, brings the lower mold 304 close to the direction of the upper mold 302, and seals the semiconductor chip 104 mounted on the substrate 102 with the sealing resin 120 by compression molding. The sealing resin 120 set within the cavity of the lower mold 304 is melted and cured to thereby be compression-molded. Meanwhile, when the lower mold 304 is moved to the direction of the upper mold 302, the drive control section 330 can also move the heating portion 310 together with the lower mold 304.

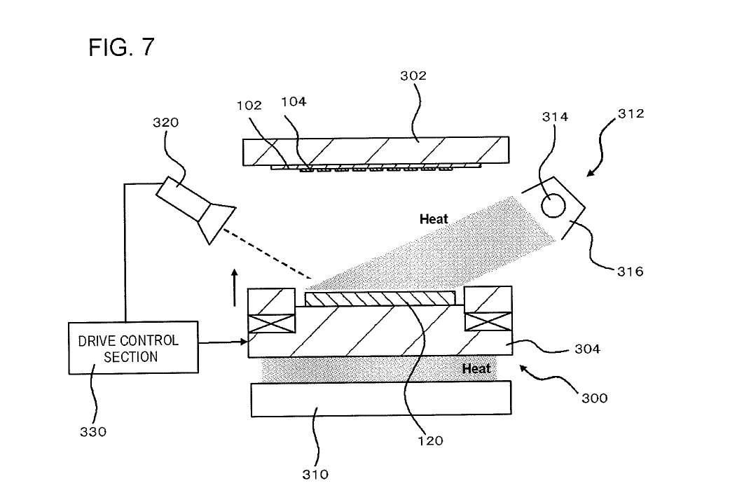

FIG. 7 is a diagram illustrating another example of the compression molding apparatus 300 in the embodiment.

Herein, the compression molding apparatus 300 has a configuration of the upper-surface heating portion different from that of the example shown in FIG. 6. Here, the compression molding apparatus 300 includes an upper-surface heating portion 312 in place of the upper-surface heating portion 340 shown in FIG. 6. The upper-surface heating portion 312 can be constituted by, for example, a heater 314 such as an infrared heater and a reflective plate 316 surrounding the heater 314. The upper surface heating portion 312 heats the lower mold 304 from obliquely upward. By such a configuration, when the lower mold 304 is moved to the direction of the upper mold 302, it is not required to move the upper-surface heating portion 312.

According to the compression molding apparatus 300 in the embodiment, it is possible to improve the heating efficiency by heating the upper surface of the sealing resin 120 of which the temperature easily becomes low at the time of compression molding, and to stably melt the sealing resin. Thereby, it is possible to perform satisfactory sealing without excessively lengthening the heating time. In addition, the temperature of the sealing resin 120 is monitored in real time, and it is confirmed that the sealing resin 120 reaches a predetermined temperature, and then compression molding is performed, thereby allowing prevention of poor sealing due to the low temperature of the sealing resin from occurring.

As described above, although the embodiments of the invention have been set forth with reference to the drawings, they are merely illustrative of the invention, and various configurations other than those stated above can be adopted.

It is apparent that the present invention is not limited to the above embodiment, and may be modified and changed without departing from the scope and spirit of the invention.

What is claimed is:

1. A method of manufacturing a semiconductor device, comprising:
determining whether or not the viscosity of a sealing resin at a first temperature lower than the melting temperature of said sealing resin is less than or equal to a first reference value which prevents poor sealing from occurring at said first temperature, for each lot in which the corresponding sealing resin is manufactured;
selecting said sealing resin of said lot when said viscosity of said sealing resin at said first temperature is less than or equal to said first reference value;
introducing said sealing resin selected in said selecting said sealing resin into a mold of a compression molding apparatus; and
sealing a semiconductor chip mounted over a substrate with said sealing resin by compression molding using said mold heated at a second temperature higher than said first temperature after said introducing said sealing resin.

2. The method of manufacturing a semiconductor device as set forth in claim 1, wherein said first reference value is 95 Pa·sec.

3. The method of manufacturing a semiconductor device as set forth in claim 1, wherein said first temperature is set on the basis of variation in the temperature of said sealing resin between the start of compression molding and the end thereof in said sealing the semiconductor chip mounted over the substrate with said sealing resin by compression molding using said mold heated at a second temperature.

4. The method of manufacturing a semiconductor device as set forth in claim 1, wherein said first temperature is 120° C.

5. The method of manufacturing a semiconductor device as set forth in claim 1, wherein said second temperature is equal to or higher than the melting temperature of said sealing resin.

6. The method of manufacturing a semiconductor device as set forth in claim 1, wherein said second temperature is 175° C.

7. The method of manufacturing the semiconductor device as set forth in claim 1,
wherein said semiconductor chip is electrically connected to said substrate through a bonding wire, and
wherein, in said sealing said semiconductor chip over said substrate with said sealing resin by compression molding, said bonding wire is sealed with said sealing resin.

8. The method of manufacturing the semiconductor device as set forth in claim 1, wherein in said selecting said sealing resin of said lot, it is determined whether the viscosity at said first temperature is less than or equal to said first reference value, for each lot in which the corresponding sealing resin is manufactured, for said sealing resin of which the viscosity at said second temperature is less than or equal to a second reference value which prevents poor sealing from occurring at said second temperature.

9. The method of manufacturing the semiconductor device as set forth in claim 1, wherein said selecting said sealing resin of said lot includes measuring the viscosity of the corresponding sealing resin for each lot in which said sealing resin is manufactured, and
it is determined whether the viscosity at said first temperature is less than or equal to said first reference value, for each lot in which the corresponding sealing resin is manufactured, on the basis of the measurement result in said measuring the viscosity.

10. The method of manufacturing the semiconductor device as set forth in claim 1, further comprising:
heating said mold to said second temperature before said sealing said semiconductor chip mounted over said substrate.
